(19) United States
(12) Patent Application Publication
(10) Pub. No.: US 2008/0315317 A1
(43) Pub. Date: Dec. 25, 2008

(54) SEMICONDUCTOR SYSTEM HAVING COMPLEMENTARY STRAINED CHANNELS

(75) Inventors: Chung Woh Lai, Singapore (SG); Yong Meng Lee, Singapore (SG); Wenhe Lin, Singapore (SG); Khee Yong Lim, Singapore (SG); Young Way Teh, Singapore (SG); Wee Leng Tan, Singapore (SG); Hui Peng Koh, Singapore (SG); John Sudijono, Singapore (SG); Liang-Choo Hsia, Singapore (SG)

Correspondence Address: LAW OFFICES OF MIKIO ISHIMARU, 333 W. EL CAMINO REAL, SUITE 330, SUNNYVALE, CA, 94087, US

(73) Assignee: CHARTERED SEMICONDUCTOR MANUFACTURING LTD., Singapore (SG)

(21) Appl. No.: 11/767,449

(22) Filed: Jun. 22, 2007

(51) Int. Cl. H01L 27/092; H01L 21/8238

(52) U.S. Cl. 257/369; 438/199; 257/E27.062; 257/E21.632

(57) ABSTRACT

A semiconductor system is provided including providing a semiconductor substrate; forming PMOS and NMOS transistors in and on the semiconductor substrate; forming a tensile strained layer on the semiconductor substrate; and relaxing the tensile strained layer around the PMOS transistor.

### TECHNICAL FIELD

The present invention relates generally to semiconductor systems, and more particularly to strained silicon semiconductor systems.

### BACKGROUND ART

Electronic products are used in almost every aspect of life, and the heart of these electronic products is the integrated circuit or semiconductor device. Semiconductor devices are used in everything from airplanes and televisions to wristwatches.

Semiconductor devices are made in and on wafers by extremely complex systems that require the coordination of hundreds or even thousands of precisely controlled processes to produce a finished semiconductor wafer. Each finished semiconductor wafer has hundreds to tens of thousands of semiconductor dies, each worth as much as hundreds or thousands of dollars.

Semiconductor dies are made up of hundreds to billions of individual components. One common component is the transistor. The most common and important semiconductor technology presently used is silicon-based, and the most preferred silicon-based semiconductor technology is a Complementary Metal Oxide Semiconductor (CMOS) technology.

The principal elements of CMOS technology generally consist of a silicon substrate having trench isolation regions surrounding n-channel or p-channel transistor areas. The transistor areas contain polysilicon gates on a silicon oxide dielectric, or gate oxides, over the doped silicon substrate. The silicon substrate adjacently opposite the polysilicon gate is lightly doped to become conductive. The lightly doped regions of the silicon substrate are referred to as “shallow source/drain regions,” or “source/drain extension regions” which are separated by a channel region in the substrate or a substrate well beneath the polysilicon gate.

A spacer, referred to as a “sidewall spacer”, of an oxide or nitride on the sides of the polysilicon gate allows deposition of additional doping to form more heavily doped regions of the shallow source/drain regions, which are called “deep source/drain regions.” The shallow and deep source/drain regions are collectively referred to as source/drain regions.

To complete the transistor, a dielectric layer is deposited to cover the polysilicon gate, the spacer, and the silicon substrate. To provide electrical contacts for the transistor, openings are etched in the dielectric layer to the polysilicon gate and the source/drain regions. The openings are filled with a silicide and a metal to form electrical contacts. To complete the integrated circuits, the contacts are connected to additional levels of wiring in additional levels of dielectric material to the outside of the dielectric material.

In operation, an input signal to the gate contact to the polysilicon gate controls the flow of electric current from one source/drain contact through one source/drain region through the channel to the other source/drain region and to the other source/drain contact.

Metal oxide semiconductor field effect transistor (MOSFET) devices are well known and widely used in the electronics industry. The carrier mobility of a MOSFET device is an important parameter because of its direct influence on the drive current and switching performance. In standard MOSFET technology, the channel length and gate dielectric thickness are reduced to improve current drive and switching performance. However, reducing the gate dielectric thickness can compromise device performance because of the associated increase in gate leakage current.

It has been shown that in p-channel MOSFETs, a channel region under compressive strain enhances hole mobility in the channel region. Accordingly, a higher drive current can be obtained resulting in faster operating MOSFETs.

It has been shown that in n-channel MOSFETs, a channel region under tensile strain enhances electron mobility in the channel region. Accordingly, a higher drive current can be obtained resulting in faster operating MOSFETs.

One strained channel silicon semiconductor includes strained silicon (Si) on a relaxed silicon/germanium (SiGe) substrate to obtain the strains needed. However, these devices have the disadvantages of self-heating and a tight thermal budget window. A higher strain also is required for PMOS transistors to obtain enhanced hole mobility.

One proposed solution involves etching a recess in the area of the source/drain regions and depositing SiGe or silicon/germanium/carbon (SiGeC) in the recess to strain the channel of the transistor. This method involves an additional etching step that adds to the cost of manufacturing the devices.

Another proposed solution involves forming germanium (Ge) on an insulator by oxidation of SiGe on an insulating material, such as an oxide. This approach employs Ge as the channel of the transistor. This approach requires an insulating layer that also adds to the cost of manufacturing the devices.

Solutions to these problems have been long sought but prior developments have not taught or suggested any solutions and, thus, solutions to these problems have long eluded those skilled in the art.

### DISCLOSURE OF THE INVENTION

The present invention provides a semiconductor system including providing a semiconductor substrate; forming PMOS and NMOS transistors in and on the semiconductor substrate; forming a tensile strained layer on the semiconductor substrate; and relaxing the tensile strained layer around the PMOS transistor.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF THE DRAWINGS

FIG. 1 is a cross-sectional view of a semiconductor at an intermediate stage of manufacture in accordance with an embodiment of the present invention;

FIG. 2 is the structure of FIG. 1 during relaxation of a tensile strained layer;

FIG. 3 is the structure of FIG. 2 after formation of gate dielectrics;

FIG. 4 is the structure of FIG. 3 after formation of gates;

FIG. 5 is the structure of FIG. 4 after formation of gate spacers;

FIG. 6 is the structure of FIG. 5 during a deep source/drain implantation;

FIG. 7 is the structure of FIG. 6 after removing a photoresist;

FIG. 8 is a cross sectional view of a semiconductor system at an intermediate stage of manufacture in accordance with another embodiment of the present invention;

FIG. 9 is the structure of FIG. 8 after removal of a compressive gate spacer;

FIG. 10 is the structure of FIG. 9 forming a tensile strain layer;

FIG. 11 is the structure of FIG. 10 during relaxation of the tensile strain layer;

FIG. 12 is the structure of FIG. 11 after removal of a PMOS source/drain implant mask;

FIG. 13 is a flow chart of a semiconductor system in accordance with an embodiment of the present invention.

### BEST MODE FOR CARRYING OUT THE INVENTION

In the following description, numerous specific details are given to provide a thorough understanding of the invention. However, it will be apparent that the invention may be practiced without these specific details. In order to avoid obscuring the present invention, some well-known process steps are not disclosed in detail.

Additionally, the drawings showing embodiments of the present invention are semi-diagrammatic and not to scale and, particularly, some of the dimensions are for the clarity of presentation and are shown greatly exaggerated in the FIGs. Generally, the device can be operated in any orientation.

The term “horizontal” as used herein is defined as a plane parallel to the conventional plane or surface of the substrate, regardless of its orientation. The term “vertical” refers to a direction perpendicular to the horizontal as just defined. Terms, such as “above”, “below”, “bottom”, “top”, “side” (as in “sidewall”), “higher”, “lower”, “over”, and “under”, are defined with respect to the horizontal plane. The term “on” means that there is direct contact between elements.

The term “processing” as used herein includes deposition of material or photoresist, patterning, exposure, development, etching, cleaning, and/or removal of the material or photoresist as required in forming a described structure.

In the disclosure below, PMOS and NMOS transistors are shown as being adjacent for ease of explanation. It will be understood that there will be numerous transistors and the PMOS and NMOS transistors may be distributed across a semiconductor device.

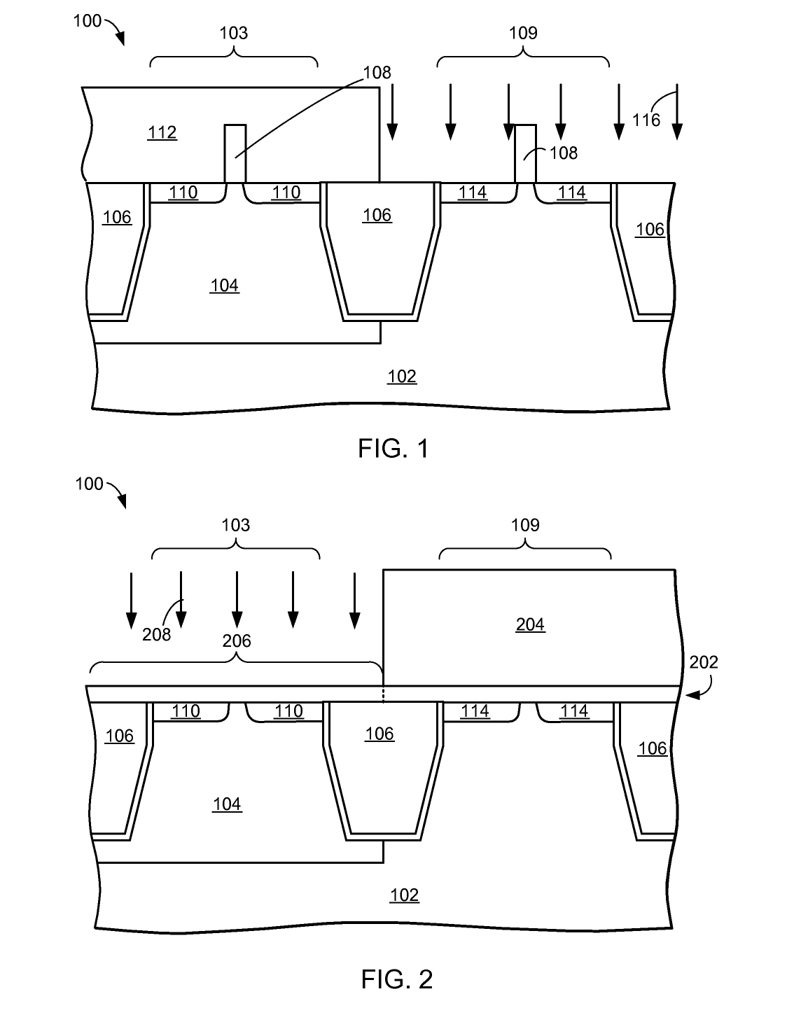

Referring now to FIG. 1, therein is shown a cross-sectional view of a semiconductor system 100 at an intermediate stage of manufacture in accordance with one embodiment of the present invention.

The semiconductor system 100 includes a semiconductor substrate 102, which is a lightly doped with a dopant of a first conductivity type, such as a p-type dopant. In a region where a transistor of a first conductivity type will formed, such as a PMOS transistor 103, a well 104, of a second conductivity type, such as an n-doped well, is formed by diffusion and/or implant processing.

The semiconductor substrate 102 also has shallow trench isolations (STIs) 106, to isolate the transistors to be manufactured in and on the semiconductor substrate 102. The STIs 106 are provided by forming trenches, such as by etching, in the semiconductor substrate 102. The trenches are then filled with an insulating material after forming a liner, to provide the STIs 106, substantially coplanar with the semiconductor substrate 102 by stopping at the semiconductor substrate 102 prior to formation of a source/drain region 110.

A shallow implantation mask layer (not shown) is deposited and processed to form a shallow implantation gate mask 108 and a first photoresist (not shown) is deposited over the region where a transistor of a second conductivity type will be formed, such as an NMOS transistor 109. The shallow implantation gate mask 108 over the region of the PMOS transistor 103 has been used as a mask for implantation of shallow source/drain regions 110 for the PMOS transistor 103. The shallow source/drain regions 110 are lightly doped by ion implantation with a dopant such as a p⁺ dopant. An optional halo implantation may have been performed.

In FIG. 1, a PMOS protective mask 112 has been deposited and processed to cover the region of the PMOS transistor 103. The shallow implantation gate mask 108 over the region of the PMOS transistor 103 is used as a mask for implantation of shallow source/drain regions 114 for the PMOS transistor 103. The shallow source/drain regions 114 are lightly doped by ion implantation 116 with a dopant such as an n⁺ dopant. An optional halo implantation may be performed.

Referring now to FIG. 2 therein is shown the structure of FIG. 1 during relaxation of a tensile strained layer 202. The PMOS protective mask 112 and the shallow implantation gate masks 108 of FIG. 1 are removed.

The tensile strained layer 202 is deposited by a process such as hetroepitaxial deposition and is formed from a material that has an atomic size larger than the atomic size of the semiconductor substrate 102. The hetroepitaxial growth of the tensile strained layer 202 upon the semiconductor substrate 102 and the atomic size of the deposited material causes what is described as a high tensile strain into the shallow source/drain regions 110. The tensile strained layer 202 is thus described as a high tensile strain layer. In one embodiment, the tensile strained layer 202 is of silicon nitride deposited by thermal chemical vapor deposition (CVD) or Plasma Enhanced CVD (PECVD) on the semiconductor substrate 102.

A relaxation implant mask 204 is deposited and processed on the tensile strained layer 202 to cover the region of the NMOS transistor 109. A relaxation ion implantation 208, of ions of a material such as germanium, is performed into the tensile strained layer 202 above the region of the PMOS transistor 103.

After removal of the relaxation implant mask 204, a rapid thermal annealing step is performed with an option of msec laser anneals. The very short duration rapid thermal anneals ensure that the heavily germanium implanted exposed tensile strained layer 202 is still relaxed after the anneals and forming the layer 206. The relaxation of the tensile strained layer 202 relaxes the strain in the semiconductor substrate 102 underneath the relaxed layer 206. While tensile strain in the PMOS transistor 103, when completed, would reduce hole mobility and switching performance, tensile-relaxed or near neutral strain ensures that hole mobility and thus switching performance are not compromised.

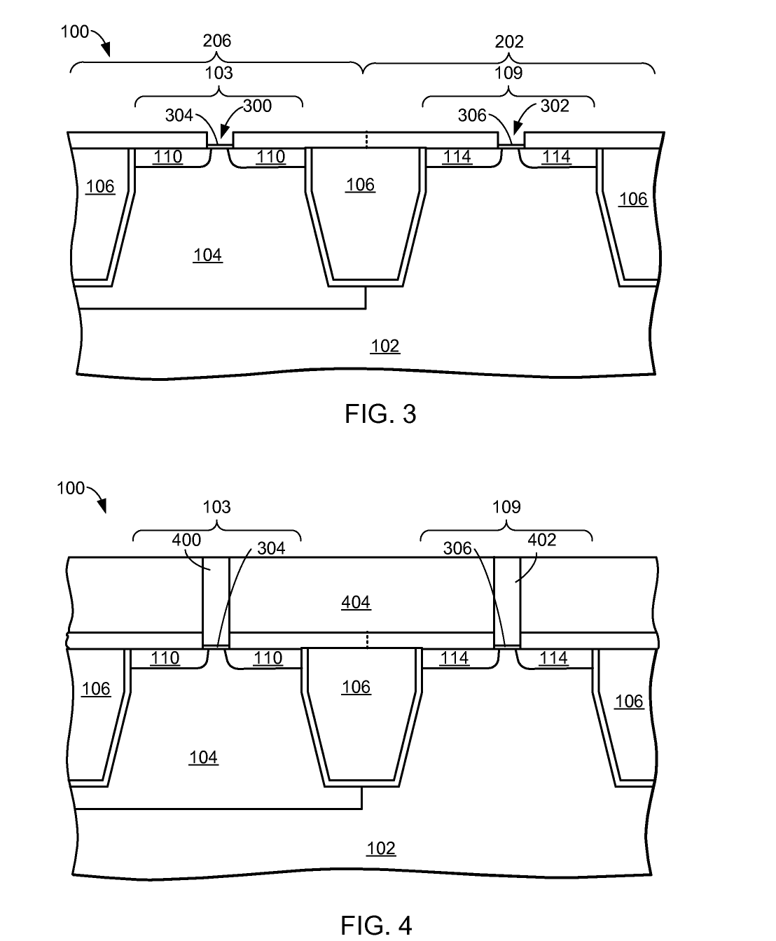

Referring now to FIG. 3, therein is shown the structure of FIG. 2 after formation of gate dielectrics 300. The relaxation implant mask 204 of FIG. 2 is removed and a gate dielectric mask (not shown) is deposited and processed.

The gate dielectric mask is used to form gate dielectric openings 300 and 302. A cleaning step is then performed to prepare the surface in the gate dielectric openings 300 and 302 for formation of gate dielectrics 304 and 306 respectively. The gate dielectrics 304 and 306 may be formed by a process such as growth by plasma nitration forming a silicon nitrate (Si₃N₄) film.

Removal of the relaxation implant mask 204 exposes the tensile strained layer 202, which maintains the tensile stress in the semiconductor substrate 102 in the region of the NMOS transistor 109. Tensile stress in the NMOS transistor 109 increases hole mobility and switching performance above that in a non-stressed NMOS transistor.

Referring now to FIG. 4, therein is shown the structure of FIG. 3 after formation of gates 400 and 402. A gate formation mask 404 is deposited and patterned. The gates 400 and 402, of a material such as polysilicon or metal, are deposited over the gate dielectrics 304 and 306, respectively in the gate formation mask 404.

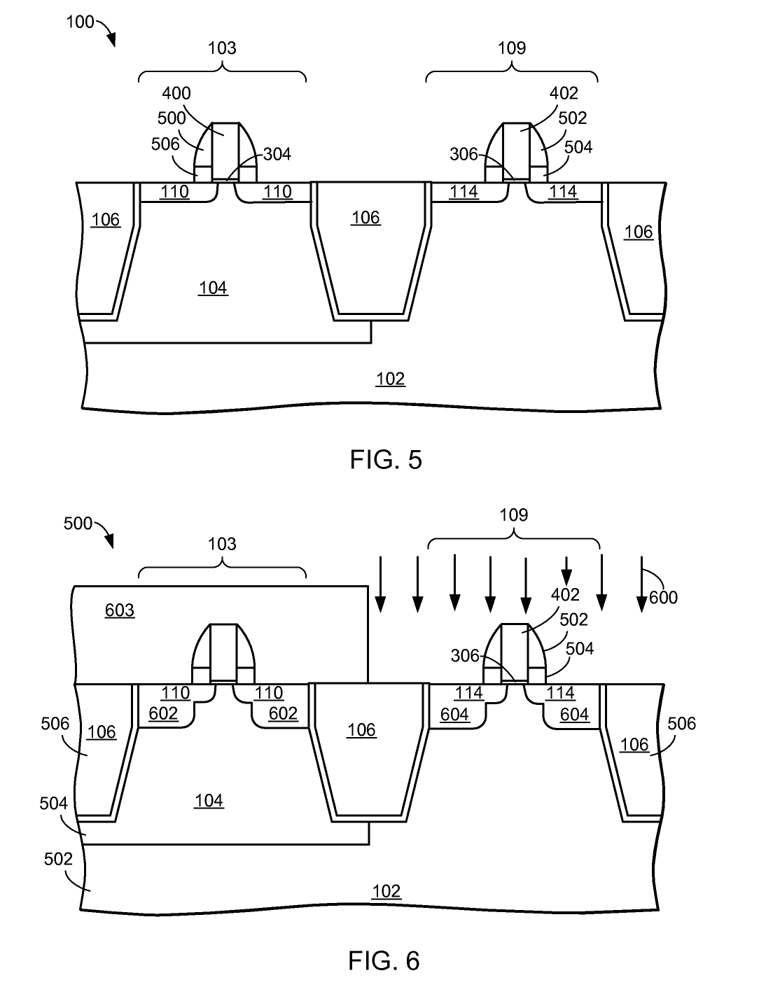

Referring now to FIG. 5, therein is shown the structure of FIG. 4 after formation of gate spacers 500 and 502. The gate formation mask 404 is removed and a spacer layer (not shown) is deposited over the tensile strained layer 202 and the relaxed layer 206. The spacer layer can consist of more than one layer of materials, such as by forming a silicon dioxide (SiO₂) layer followed by the forming of a silicon nitride (SiN) layer.

Anisotropic etching processes etch the spacer layer to form the gate spacers 500 and 502 and etch the tensile strained layer 202 and the relaxed layer 206 to form a strained spacer base 504 and a relaxed spacer base 506, respectively.

Referring now to FIG. 6, therein is shown the structure of FIG. 5 during a deep source/drain implantation 600. A first photoresist (not shown) is deposited and processed over the region of the NMOS transistor 109 and used as a mask for implantation of deep source/drain regions 602 for the PMOS transistor 103. The deep source/drain regions 602 are highly doped by ion implantation with a dopant such as a p⁺ dopant.

In FIG. 6, a deep source/drain implantation mask 603 has been deposited and processed over the region of the PMOS transistor 103 and is being used as a mask for implantation of deep source/drain regions 604. The deep source/drain regions 604 are highly doped by ion implantation with a dopant such as an n⁺ dopant.

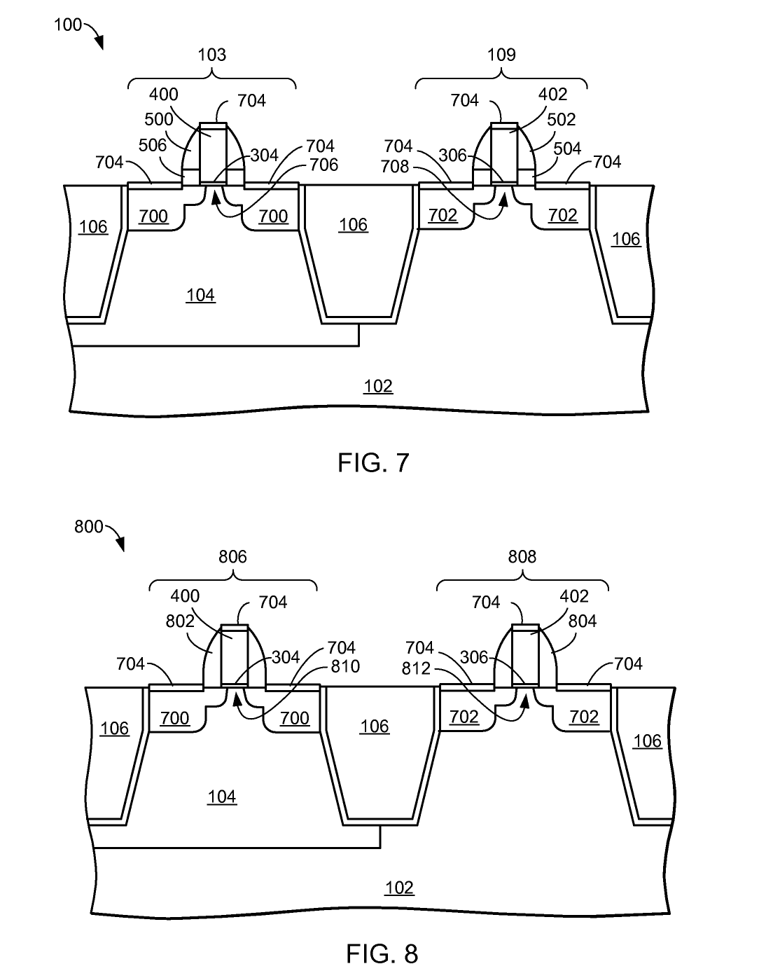

Referring now to FIG. 7, therein is shown the structure of FIG. 6 after removing the deep source/drain implantation mask 603. A thermal anneal has been performed and the shallow and deep source/drain regions have been merged into source/drain regions 700 and 702.

A silicide or salicide 704 has been formed on the source/drain regions 700 and 702 and on the gate 402.

It has been discovered that the above steps cause the PMOS transistor 103 and the NMOS transistor 109 to respectively have unstressed and stressed channel regions 706 and 708 that have high hole mobility and switching performance. High hole mobility is defined as being in the range of 300 to 1000 cm²/V.s. and high switching performance is defined as 9 to 15 ps/stage@1 nA/um.

Referring now to FIG. 8, therein is shown a cross sectional view of a semiconductor system 800 at an intermediate stage of manufacture in accordance with another embodiment of the present invention. The semiconductor system 800 is similar to the semiconductor system 100 except that the tensile strained layer 202 of FIG. 2 was not formed and gate spacers 802 and 804 are formed as compressive spacers and in contact with the semiconductor substrate 102.

It has been found that nitride spacers can be deposited having tensile or compressive stress as desired by adjusting the combinations of high and low frequency power used in the PECVD process. The degree of stress can be controlled without undue experimentation.

The compressive stress on the PMOS transistor 806 enhances hole mobility.

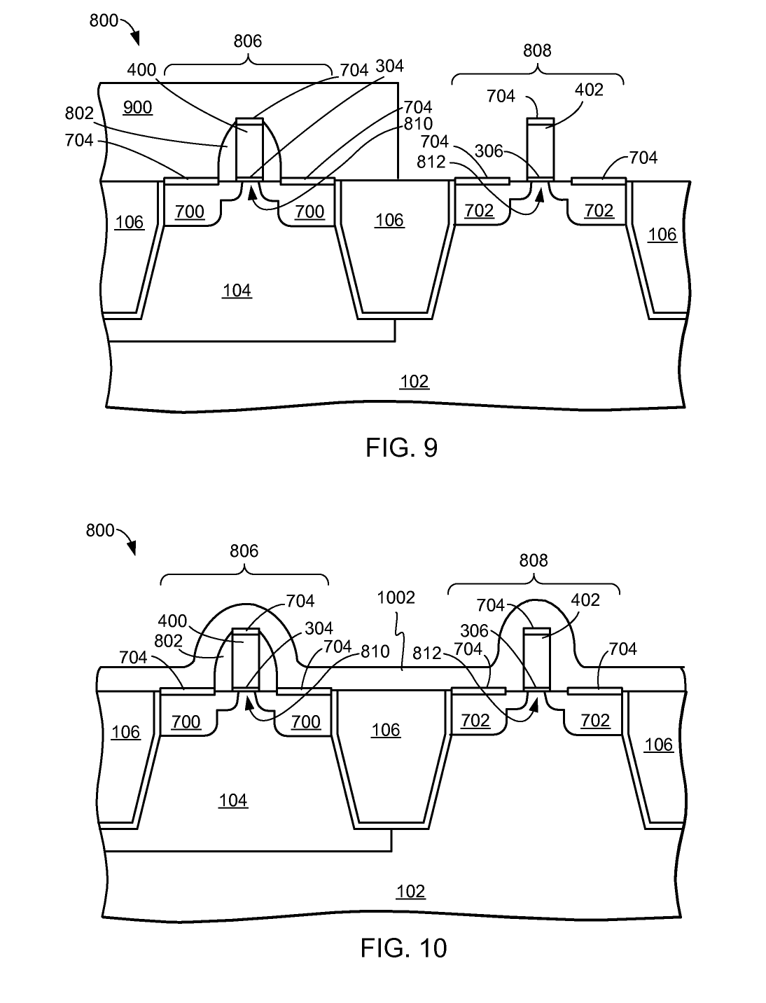

Referring now to FIG. 9, therein is shown the structure of FIG. 8 after removal of the gate spacer 804 of FIG. 8. A spacer protective mask 900 is deposited and processed over the PMOS transistor 806 to allow removal, by a process such as plasma or wet etching, of the gate spacer 804 of the NMOS transistor 808.

Referring now to FIG. 10, therein is shown the structure of FIG. 9 after forming a tensile strained layer 1002. The spacer protective mask 900 of FIG. 9 is removed.

The tensile strained layer 1002 is deposited by a process such as CVD. In one embodiment, the tensile strained layer 1002 is of silicon nitride deposited by thermal or PECVD on the semiconductor substrate 102.

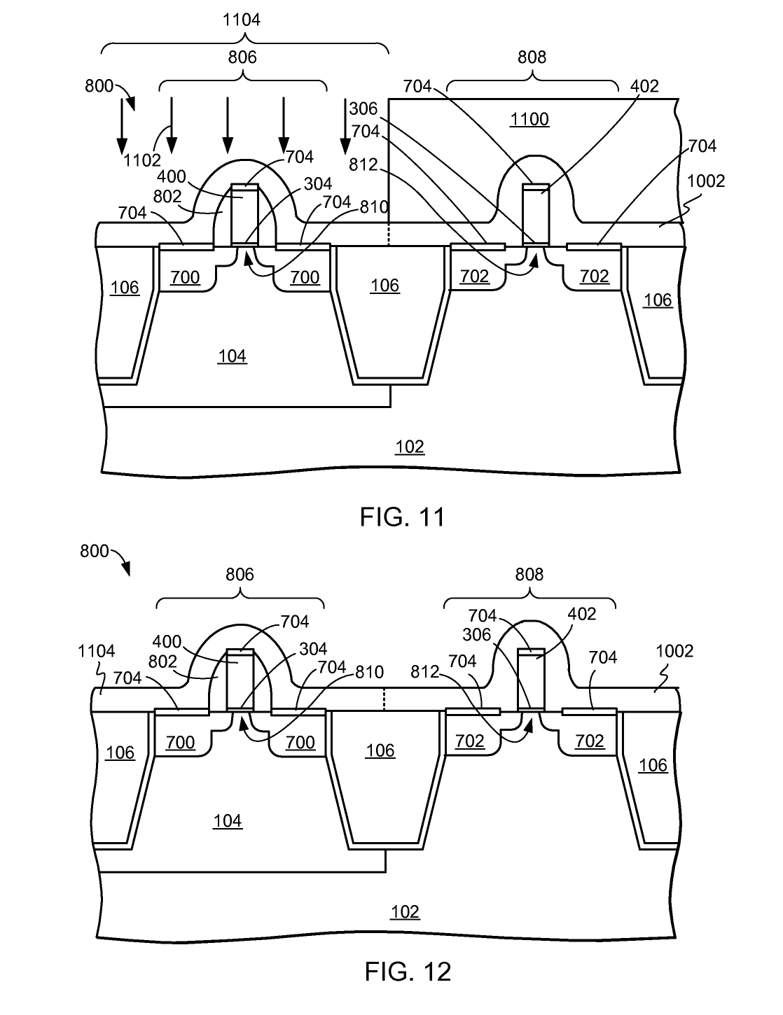

Referring now to FIG. 11, therein is shown the structure of FIG. 10 during relaxation of the tensile strained layer 1002.

A relaxation implant mask 1100 is deposited and processed on the tensile strained layer 1002 to cover the region of the NMOS transistor 808. A relaxation ion implantation 1102, of ions of a material such as germanium, is performed into the tensile strained layer 1002 above the region of the PMOS transistor 806.

While tensile strain in the PMOS transistor 806 would reduce hole mobility and switching performance, the lack of tensile strain does not reduce hole mobility and switching performance.

Referring now to FIG. 12, therein is shown the structure of FIG. 1 after removal of the relaxation implant mask 1100 of FIG. 11.

It has been discovered that the above steps cause the PMOS transistor 806 and the NMOS transistor 808 to respectively have unstressed and stressed channel regions 810 and 812.

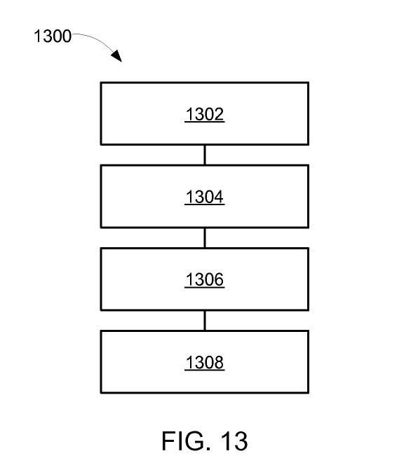

Referring now to FIG. 13, therein is shown a flow chart of a method 1300 for manufacturing a semiconductor in accordance with an embodiment of the present invention. The method 1300 includes providing a semiconductor substrate in a block 1302; forming a PMOS and NMOS transistors in and on the semiconductor substrate in a block 1304; forming a tensile strained layer in a block 1306; and relaxing the tensile strained layer around the PMOS transistor in a block 1308.

Thus, it has been discovered that the method and apparatus of the present invention furnish important and heretofore unavailable solutions, capabilities, and functional advantages for manufacturing a semiconductor having a strained channel. The resulting process and configurations are straightforward, economical, uncomplicated, highly versatile, and effective, use conventional technologies, and are thus readily suited for manufacturing semiconductors that are fully compatible with conventional manufacturing processes and technologies.

The invention provides selective control of compressive and tensile strain regions thereby improving PMOS and NMOS transistors performance. A sidewall spacer base layer above source/drain extensions and below gate sidewall spacers creates strain in MOSFET transistor channels. The conventional spacers can alternatively be structures that impart a net compressive or tensile strain to PMOS or NMOS channels respectively. For example, sidewall spacers can be replaced by strain inducing structures of one or more layers. The induced strain of these strain-inducing structures can be detected by changes in the majority carrier mobility of MOSFET transistors.

One of the challenges in modern CMOS device design is to improve NMOS devices without degrading PMOS devices, and vice versa. In this disclosure, a scheme to do exactly that is shown. In one embodiment a compressive strain material is used during spacer formation for both devices. After the standard source/drain implants, anneals and the silicide formation, the spacer on the NMOS devices are stripped, while ensuring that those on the PMOS devices are intact. Next, a highly tensile material, which also acts as an etch stop liner for interlayer dielectric contacts, is deposited across the entire wafer. To ensure that this tensile film does not degrade the PMOS transistors, a Ge implant is carried out on the PMOS regions to relax the high-tension film. NMOS transistors are shielded from this implant by a resist. The rest of the processing steps after this resist is stripped remain unchanged from a standard CMOS middle-of-line, back-end-of-line (MOL/BEOL) process scheme.

In another embodiment disclosed, a high tensile material is deposited before gate patterning and used to strain the NMOS channel and the regions near the source/drain extension and halo implants. To not degrade the performance of PMOS devices, a Ge implant is used to relax the material covering the PMOS devices with a resist covering the NMOS devices blocking this implant. This is followed by rapid thermal annealing such as by pulse laser heating, which will increase the strength of the tensile material and transfer the strain to the channel. This material remains after the gate patterning and forms the base of the spacers covering the source/drain extensions. NMOS devices with such architecture will see an improvement in performance, while PMOS device performance will not be degraded as result of this implant.

The present invention also avoids etching a recess in the area of the source/drain regions and depositing SiGe or silicon/germanium/carbon (SiGeC) in the recess to strain the channel of the transistor thereby eliminating the cost of manufacturing the semiconductors, introduced by the additional Si recess etch step.

While the invention has been described in conjunction with a specific best mode, it is to be understood that many alternatives, modifications, and variations will be apparent to those skilled in the art in light of the foregoing description. Accordingly, it is intended to embrace all such alternatives, modifications, and variations that fall within the scope of the included claims. All matters set forth herein or shown in the accompanying drawings are to be interpreted in an illustrative and non-limiting sense.

What is claimed is:

1. A semiconductor system comprising:
providing a semiconductor substrate;
forming PMOS and NMOS transistors in and on the semiconductor substrate;
forming a tensile strained layer on the semiconductor substrate; and
relaxing the tensile strained layer around the PMOS transistor.

2. The semiconductor system as claimed in claim 1 further comprising forming spacers around the PMOS and the NMOS transistors.

3. The semiconductor system as claimed in claim 1 further comprising:
forming a spacer around the PMOS transistor over the relaxed tensile strained layer;
forming a spacer around the NMOS transistors over the tensile strained layer; and
removing the relaxed tensile strained layer not under the PMOS transistor and the tensile strained layer not under the NMOS transistor.

4. The semiconductor system as claimed in claim 1 further comprising:
forming spacers around the PMOS and the NMOS transistors; and
removing the spacer around the NMOS transistor.

5. The semiconductor system as claimed in claim 1, further comprising:
forming spacers around the PMOS and the NMOS transistors;
removing the spacer around the NMOS transistor; and
forming the tensile strained layer over the PMOS and NMOS transistors.

6. A semiconductor system comprising:
providing a semiconductor substrate;
forming PMOS and NMOS transistors in and on the semiconductor substrate;
forming a tensile strained layer on the semiconductor substrate;
implanting ions for relaxing the tensile strained layer around the PMOS transistor while masking ion implantation around and preventing relaxation of the tensile strained layer around the NMOS transistor; and
annealing to relax the tensile strained layer around the PMOS transistor.

7. The semiconductor system as claimed in claim 6 further comprising forming spacers around the PMOS and the NMOS transistors.

8. The semiconductor system as claimed in claim 6 further comprising:
forming a spacer around the PMOS transistor over the relaxed tensile strained layer;
forming a spacer around the NMOS transistors over the tensile strained layer;
removing the relaxed tensile strained layer not under the PMOS transistor and the tensile strained layer not under the NMOS transistor; and
saliciding the PMOS and NMOS transistors.

9. The semiconductor system as claimed in claim 6 further comprising:
forming compressive spacers around the PMOS and the NMOS transistors;
removing the compressive spacer around the NMOS transistor; and
saliciding the PMOS and NMOS transistors.

10. The semiconductor system as claimed in claim 6 further comprising:
forming compressive spacers around the PMOS and the NMOS transistors;
removing the compressive spacer around the NMOS transistor;
saliciding the PMOS and NMOS transistors; and
forming the tensile strained layer over the PMOS and NMOS transistors and the saliciding.

11. A semiconductor system comprising:
a semiconductor substrate;
PMOS and NMOS transistors in and on the semiconductor substrate; and
a tensile strained layer on the semiconductor substrate and an unstrained layer around the PMOS transistor.

12. The semiconductor system as claimed in claim 11 further comprising spacers around the PMOS and the NMOS transistors.

13. The semiconductor system as claimed in claim 11 further comprising:
a spacer around the PMOS transistor over the unstrained layer;
a spacer around the NMOS transistor over the tensile strained layer; and
the relaxed tensile strained layer is not under the PMOS transistor sand the tensile strained layer is not under the NMOS transistor.

14. The semiconductor system as claimed in claim 11 further comprising:
a spacer only around the PMOS transistor.

15. The semiconductor system as claimed in claim 11, further comprising:
a spacer around the PMOS transistors;
the unstrained layer over the PMOS transistor; and
the strained layer over the NMOS transistor.

16. The semiconductor system as claimed in claim 11 further comprising:
further PMOS and NMOS transistors in and on the semiconductor substrate the unstrained layer includes germanium ions; and
the tensile strained layer does not include germanium ions.

17. The semiconductor system as claimed in claim 16 further comprising spacers around the PMOS and the NMOS transistors.

18. The semiconductor system as claimed in claim 16 further comprising:
spacers around the PMOS transistors over the unstrained layer and the unstrained layer only under the PMOS transistors;
spacers around the NMOS transistors over the tensile strained layer and the tensile strained layer only under the NMOS transistors; and
the PMOS and NMOS transistors having saliciding thereon.

19. The semiconductor system as claimed in claim 16 further comprising:
compressive spacers only around the PMOS transistors; and
the PMOS and NMOS transistors having saliciding thereon.

20. The semiconductor system as claimed in claim 16 further comprising:
compressive spacers only around the PMOS transistors;
the PMOS and NMOS transistors having saliciding thereon; and
the tensile strained layer over the PMOS and NMOS transistors and the saliciding.
